(19) United States
(12) Patent Application Publication
(10) Pub. No.: US 2009/0155994 A1
(43) Pub. Date: Jun. 18, 2009

(54) FORMING THIN FILM TRANSISTORS USING ABLATIVE FILMS WITH PRE-PATTERNED CONDUCTORS

(76) Inventors: Gilbert A. Hawkins, Mendon, NY (US); Peter A. Stolt, Edina, MN (US); M. Zaki Ali, Mendota Heights, MN (US)

Correspondence Address: Frank Pincelli;Patent Legal Staff, Eastman Kodak Company, 343 State Street, Rochester, NY, 14650-2201, US

(21) Appl. No.: 11/954,319

(22) Filed: Dec. 12, 2007

(51) Int. Cl. H01L 21/4763; B32B 15/04

(52) U.S. Cl. 438/618; 428/457; 257/E21.495

(57) ABSTRACT

An ablative film comprising a substrate; at least one ablative layer that is removable by exposure to radiation; one or more deposited conductors; and an active layer including a semiconductor material surrounded at least partially by a dielectric.

### FIELD OF THE INVENTION

This invention relates generally to the field of thin film transistor fabrication, including fabrication of thin film transistors on flexible substrates, and particularly to low temperature means for inexpensively forming high quality, interconnected transistors on polymer substrates using a very small number of processing steps. More specifically, the invention discloses processes providing thin film transistors using laser ablatable films having pre-patterned conductors.

### BACKGROUND OF THE INVENTION

Conventional silicon transistor technology, such as that practiced in the fabrication of Very Large Scale Integrated (VLSI) circuits, is unchallenged for device performance in applications such as computer processors. However, the cost per unit area of VLSI processing is high and the size of the monolithically integrated devices is limited to a fraction of the size of the largest silicon wafer technology, which today is 300 mm. For some applications, for example flat panel displays, the sizes of the substrates (greater than 1 meter diagonal) are incompatible with the size restrictions of VLSI and the cost requirements are incompatible with VLSI processing costs. For these large areas, low cost applications, thin film amorphous and microcrystalline transistor technology on glass panels is the current technology of choice for the backplane electronics. Other thin film transistor applications include devices made on flexible substrates, such as plastics and metal foils, etc. All these applications use processing steps that are lower in temperature than those used in integrated circuit technology, since the substrates generally cannot withstand the high temperatures used in conventional silicon technology. For example, they cannot withstand temperatures of 900 to 1000 degrees C. typically used for growth of oxides and implant anneals in single crystal silicon technology. For these applications, transistors based on amorphous silicon, microcrystalline silicon, and organic materials have been developed which can be processed at relatively low temperatures. Their performance is adequate for today's flat panel displays, but none exhibit the speed, insensitivity to environmental conditions, and other high performance characteristics of conventional silicon processed at high temperatures.

While some developments have been made in thin film transistor technologies for devices that can be processed at relatively low temperatures, for example laser annealed silicon films or low temperature annealed polycrystalline silicon films on glass, the aggregate of processing steps for such thin film technologies required to provide integrated transistor arrays is still very large, and yields and cost have suffered. Co-pending application, Ser. No. 11/737,187 filed Apr. 19, 2007, discloses interconnection of microsized devices to form low cost, high performance circuits on low-temperature substrates. Transistor circuits on such microsized devices are typically formed on conventional silicon wafers with conventional silicon processing and must therefore be made prior to the process of microsized device interconnection and positioned individually on the substrate prior to microsized device interconnection. For future applications, it would clearly be desirable to directly fabricate thin film transistors on the low temperature substrates while retaining the performance, speed, and stability of conventional silicon devices. Preferably, such transistors would be fabricated in arbitrary configurations during the same processing sequence as they interconnect themselves.

### SUMMARY OF THE INVENTION

In copending application, Ser. No. 11/737,187 filed Apr. 19, 2007, a process is disclosed for using ablative films to achieve interconnections between micro-sized devices of a variety of types. For the case of electrical interconnections, this process involves forming deliberately located channels in which are deposited conductive inks that wick into contact portions of the micro-sized devices to ensure the reliable connection of electric leads to the devices or “die.” The current invention supplements this process by providing means for forming simultaneously active circuit elements having the functionality of the micro-sized devices of copending application, Ser. No. 11/737,187, without the necessity of making the micro-sized devices independently; that is, the active circuit elements are formed in processes similar to and simultaneously applied with those required in forming interconnections in copending application, Ser. No. 11/737,187.

In accordance with the present invention, low cost thin film transistors and circuits are formed by simple processes on substrates which cannot be subjected to high temperatures. Yet these transistors and circuits may have the performance, speed, and stability of conventional silicon devices. Specifically, the present invention envisions a process of forming thin film transistors comprising: providing an ablative film having a substrate with at least one ablative layer, a layer of active material, and a pre-patterned thin film conductor; forming channels in the ablative layer by exposure of the ablative film to radiation, at least some channels extending to the layer of active material; and providing at least one conductive material in the channels to form multiple electrical connections to the active material and the pre-patterned thin film conductor.

### ADVANTAGEOUS EFFECT OF THE INVENTION

Advantageously, the circuits provided by the present invention are produced at low cost and with few process steps.

Also advantageously, the circuits so formed are produced at very low processing temperatures.

A feature of the present invention is that the low-cost circuits so formed are of a performance type nearly equal or exceeding the performance of high-temperature silicon circuits employed by the computer chip industry.

Another feature is that active materials and patterned conductive materials are both provided within the ablative film prior to processing the ablative film to form particular types of circuits or circuit elements such as transistors and that the so configured ablative films may be packaged and stored prior to processing.

Another feature is that the patterned conductive materials provided within the ablative film prior to processing the ablative film enable very high transistor performance for a wide variety of active materials.

These and other aspects, objects, features and advantages of the present invention will be more clearly understood and appreciated from a review of the following detailed description of the preferred embodiments and appended claims, and by reference to the accompanying drawings.

### BRIEF DESCRIPTION OF THE DRAWINGS

FIG. 1a is a cross-section of a prior art ablative film having two energy absorbing layers on a substrate which does not appreciably absorb radiation;

FIG. 1b is a cross-section of a prior art ablative film having four layers on a substrate, some of which are energy absorbing layers;

FIGS. 2a and 2b illustrate in cross-section and top-view, respectively, prior art formation of a channel in an ablative film having two energy absorbing layers on a substrate;

FIG. 2c illustrates in cross-section a prior art process for forming an electrically conductive material in an ablated channel in an ablative film having two energy-absorbing layers;

FIG. 3 illustrates in cross-section a prior art process for forming a circuit including an electrical connection to an active element containing transistors;

FIGS. 4a and 4b illustrate in cross-section an ablative film in accordance with the present invention comprising a single ablative layer, a semiconductor active material layer, and a pre-deposited metal film;

FIG. 4c is a top view of FIG. 4b;

FIGS. 4d and 4e show an alternative related embodiment in which the active material covers the central section of metal but is distanced from the inner edges of the outer metal strips;

FIGS. 5 illustrates in cross-section a related alternative embodiment of an ablative film comprising a single ablative layer, a semiconductor active material layer, a substrate, and a single metal film deposited as a strip on the substrate;

FIGS. 6a and 6b show an alternative embodiment, identical to that illustrated in FIG. 5, differing only in having a second ablative layer coated over the substrate;

FIGS. 7a and 7b illustrate in cross-section another preferred embodiment of the ablative film comprising two ablative layers, a semiconductor active material layer, a substrate, and a metal film deposited on the substrate as two metal strips;

FIG. 7c shows an alternative embodiment as in FIGS. 7a and 7b except there is only one ablative layer;

FIG. 8a illustrates in cross-section an embodiment of the ablative film having a pre-deposited metal film deposited as a single metal strip;

FIG. 8b illustrates in cross-section the ablative film of FIG. 8a after formation, by laser radiation from the topside, of two self-aligned ablated channels extending down to the substrate;

FIG. 8c illustrates in cross-section the ablative film of FIG. 8b after the ablated channels have been filled with a conductive material;

FIG. 9a illustrates an embodiment of the ablative film of the present invention having a metal film deposited as a single metal strip, in which the order of layers from bottom to top is substrate, ablative, metal, and active layer;

FIG. 9b illustrates in cross-section the ablative film of FIG. 9a after formation by laser radiation from the topside of the ablative film;

FIG. 9c illustrates in cross-section the ablative film of FIG. 9b after the ablated channels have been filled with a conductive material;

FIGS. 10a and 10b illustrate an alternative embodiment in cross-section in which the ablative layer forms a portion of the gate insulator and the ablative exposure is incident on the backside of the ablative film; and

FIG. 11 shows a schematic top view of circuitry created by the embodiments described above.

### DETAILED DESCRIPTION OF THE INVENTION

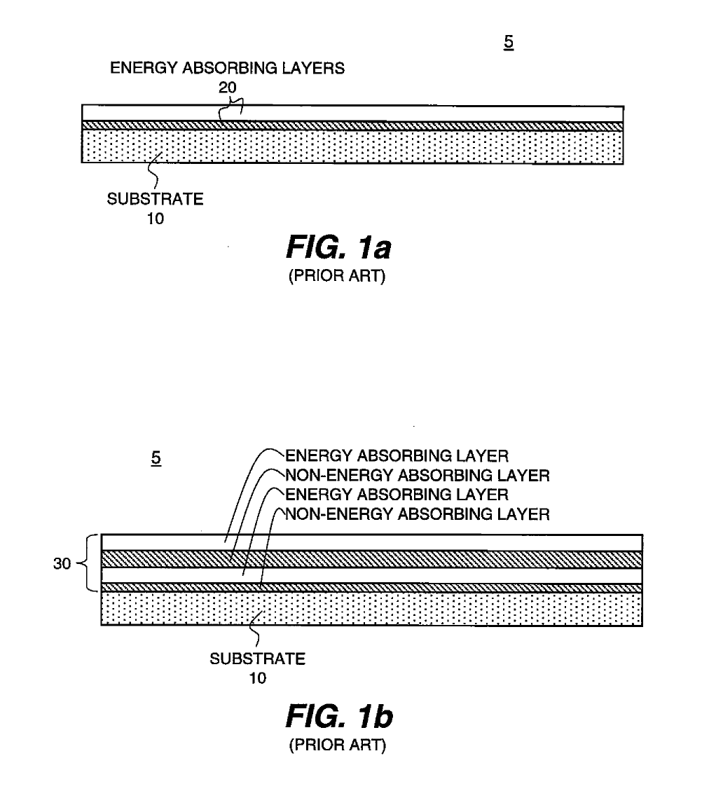

FIG. 1a is a cross-section of a prior art ablative film 5 having two energy-absorbing layers 20 on a substrate 10 which does not appreciably absorb radiation. There are no active material layers, that is layers containing semi-conductive materials, in this ablative film. During exposure to laser radiation, one or both energy absorbing layers 20 may be entirely or partially ablated away over portions of the substrate.

FIG. 1b is a cross-section of a prior art ablative film 5 having four layers 30 on a substrate 10, some of which are energy absorbing layers 20. There are no active material layers, that is layers containing semi-conductive materials, in this ablative film. During exposure to laser radiation, energy absorbing and non-energy absorbing layers in layers 30 may be entirely or partially ablated away over portions of the substrate. Generally, non-energy absorbing layers in layers 30 lying over energy absorbing layers in layers 30 are entirely ablated when one or more of the underlying layers is ablated.

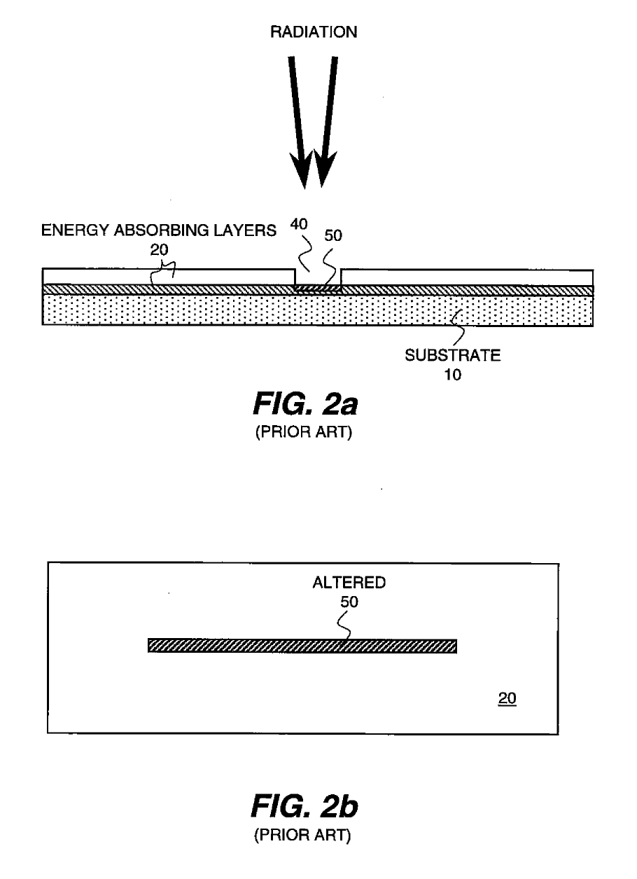

FIGS. 2a and 2b illustrate in cross-section and top-view, respectively, prior art formation of a channel 40 in an ablative film having two energy absorbing layers 20 on a substrate 10. There are no active material layers in this ablative film. The lower absorbing layer of absorbing layers 20 in the region of formation of channel 40 is not entirely ablated away but has been altered through a portion of its thickness to become altered absorbing layer 50, the alteration being one of composition or thickness caused by the formation of channel 40.

FIG. 2c illustrates in cross-section a prior art process for forming an electrically conductive material 60 in an ablated channel in an ablative film 5 having two energy-absorbing layers 20. The lower absorbing layer of absorbing layers 20 in the region of formation of channel 40 is not entirely ablated away but has been altered partially through its thickness to become partially altered absorbing layer 50, the partial alteration being one of composition or thickness caused by the formation of the channel 40.

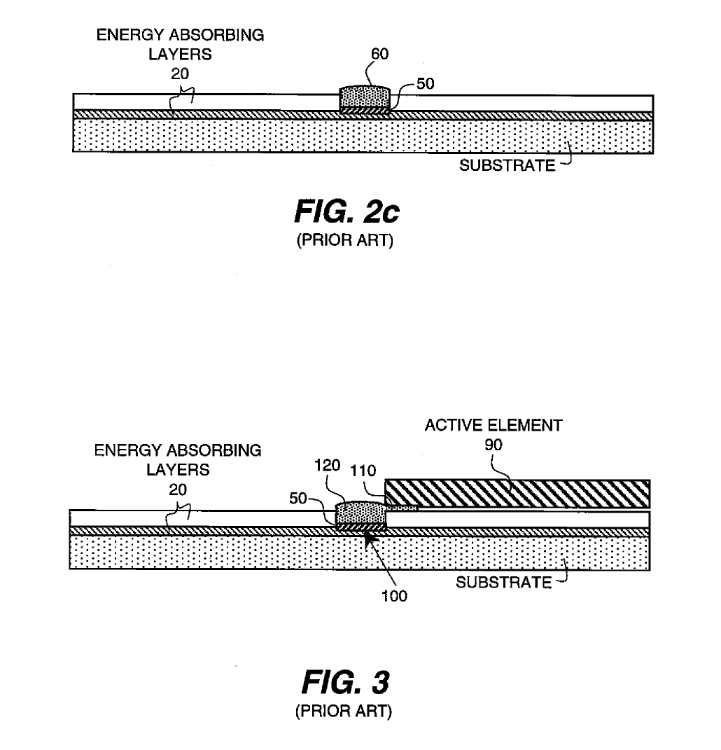

FIG. 3 illustrates in cross-section a prior art process for forming a circuit including an electrical connection 110 to an active element 90 containing transistors. Connecting material 120 wets the surface 100 of partially altered absorbing layer 50. This is further described in co-pending application, Ser. No. 11/737,187 filed Apr. 19, 2007.

Before describing the present invention, it is beneficial to define terms as used herein. In this regard, an active layer as used herein means a layer comprised all or in part of a semiconductive layer or of one or more semiconductor portions. The semiconductor layer or semiconductor portions may be surrounded partially or totally by a dielectric insulator unless specifically defined differently. It is also to be understood that portions of the semiconductor layer or of the one or more semiconductor portions may be doped, using either n-type or p-type doping, so that transistors may be formed, as is well known in the art of semiconductor fabrication. The active layer may extend across the entire ablative film or may be patterned in the plane of the ablative film (i.e. laterally patterned) so as to cover only a portion of the film.

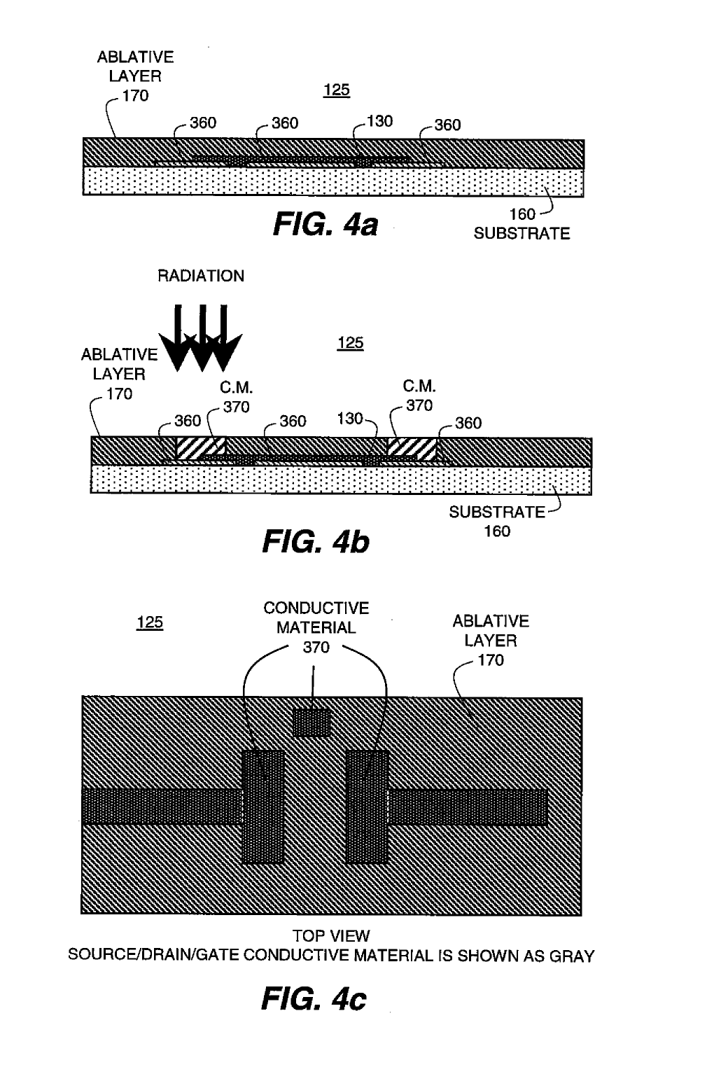

FIGS. 4a and 4b illustrate in cross-section an ablative film 125 in accordance with the present invention having a single ablative layer 170, a semiconductor active layer 130, and a substrate 160, but additionally including a pre-deposited metal film 360, deposited on the substrate 160 as three strips comprising a central strip and two adjacent outer strips. The teachings of co-filed application (93773PCW) are incorporated herein. In FIGS. 4a-4b both the active material 130 and the metal 360 have been provided in local regions (i.e. patterned laterally) and do not cover the entire substrate 160. The outer metal stripes extend beyond the lateral boundaries of the active material 130, which in this example has been patterned laterally. The metal strips 360 will become connections associated with the source, gate, and drain (left to right in FIGS. 4a and 4b) of the transistor formed in accordance with this embodiment.

FIG. 4b illustrates in cross-section the ablative film 125 of FIG. 4a after ablation of two channels through portions of the ablative layer 170 and after the ablated channels have been filled with conductive material 370. The conductive material 370 deposited in the channels forms source and drain connections between the active material and the outer metal strips, thereby minimizing the length of the conductive material 370 required. The central metal strip comprises the gate. In this example, the active layer is an active material in the form of a thin film and is covered on its bottom side by a dielectric insulator, as is well known in the art of thin film transistor fabrication.

FIG. 4c illustrates in top view the ablative film 125 of FIG. 4a after ablation of the channels and after some of the ablated channels have been filled with conductive material (light gray) 370. All exposed conductive materials are shown in gray, both the deposited conductive materials (dark gray) 370 and the pre-deposited metal (light gray) 360. The pre-deposited central metal strip comprises the gate and the ablative layer 170 over a portion of this metal strip has been removed so that subsequent electrical connection to the gate can be made. No conductive material has been deposited in this region. The remaining material shown in FIG. 4c is the ablative layer 170. It is noted that the deposited metal 360 and the ablative layer 170 are patterned laterally in a geometrical relationship to each other.

FIGS. 4d and 4e show an alternative related embodiment in which the active material 130 covers the central section of the three metal strips 360 but is distanced from the inner edges of the outer metal strips, which allows the pre-deposited conductive material strips to be more widely spaced, thereby relaxing the requirements for lateral patterning. FIGS. 4d and 4e show processing before and after ablation of the ablative layer by radiation, respectively.

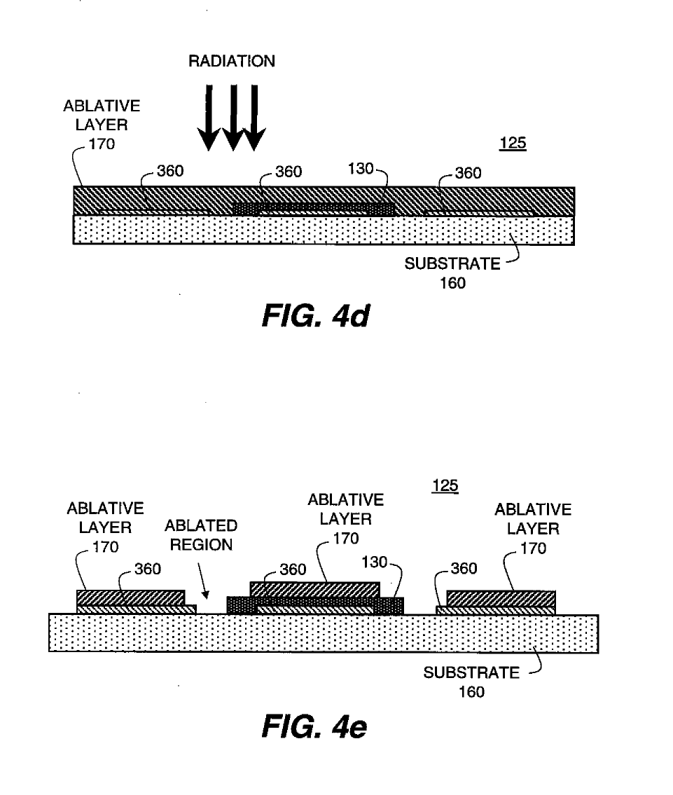

FIG. 5 illustrates in cross-section a related embodiment of an ablative film 125 comprising a single ablative layer 170, a semiconductor active layer 130, and a substrate 160 as in FIG. 4a, and a single pre-deposited metal film 360 deposited as a strip having a width on the substrate 160. The active layer 130 extends out over both sides of the single metal strip 360. It may be patterned laterally in the regions beyond the single metal strip 360 or may unpatterned, i.e. it may have the same size as the ablative film. FIG. 5 shows the ablative film 125 at the processing step after two ablative channels 380 have been formed entirely over the region of the metal strip 360, each channel 380 extending through the ablative material 170 to the top portion of the active layer 130. The transistor connections are to be completed by deposition of conductive materials (not shown) in the ablated channels 380 to form source and drain connections as has been described previously and in co-filed application (93773PCW). The pre-deposited metal film 360 comprises the gate. Although the gate extends under the source drain contacts, thereby increasing the gate capacitance, the simplicity of the process can in some circumstances outweigh the performance penalties (reduced transistor speed) of increased gate capacitance.

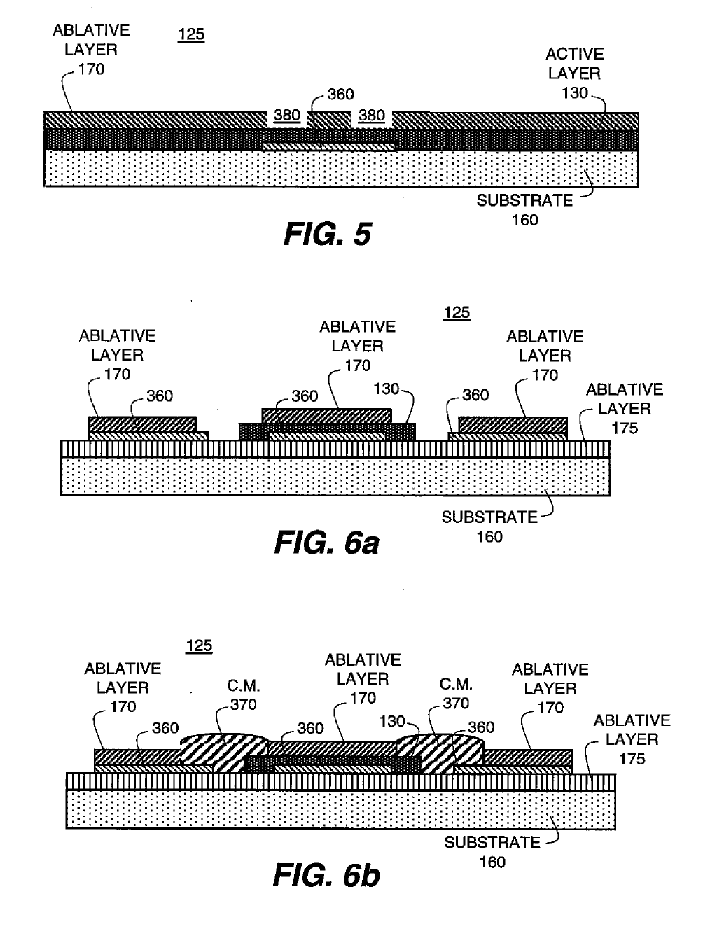

FIGS. 6a and 6b show an alternative embodiment, identical to that illustrated in FIGS. 4d and 4e, differing only in having a second ablative layer 175 coated directly over the substrate 160. In this manner, the structure of FIGS. 4d and 4e is formed but the requirements of alignment for ablation are relaxed, as the ablative radiation more easily removes the active material 130 near the central pre-deposited conductive strip. The ablative layer 175 included over the substrate 160 facilitates end contact of the outer conductive material 370 to the edges of the active material 130 by allowing portions of the active material 130 to be removed during ablation. The central metal strip 360 comprises the gate. The gate does not extend under the source drain contacts, as in the prior embodiment; thereby the gate capacitance is decreased, a desirable attribute for high-speed circuits.

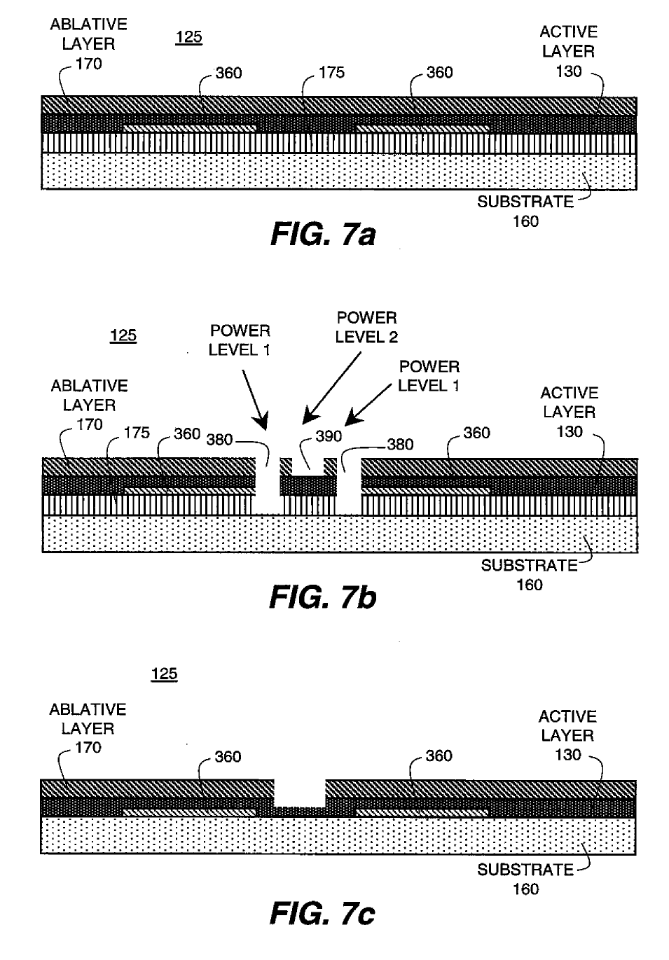

FIG. 7a illustrates in cross-section another preferred embodiment of an ablative film 125 comprising two ablative layers 170 and 175, a semiconductor active material layer 130 positioned between the two ablative layers, and a substrate 160 as in FIG. 4a, but additionally including a pre-deposited thin metal film 360 deposited on the substrate 160 as two metal strips 360. The metal strips 360 will form connections associated with the source and drain of the transistor formed in accordance with this embodiment.

FIG. 7b illustrates in cross-section the ablative film 125 of FIG. 7a after formation by laser radiation of two ablated channels 380 extending down to the substrate 160 and one ablative channel 390 extending down to the top of the active material 130. The power of the ablative radiation used to form the two ablated channels 380 is typically greater than the power used to form the one ablative channel 390 extending down to the top of the active material 130. The requirements of alignment for ablation are relaxed, since the radiation used in forming the two ablated channels 380 is reflected from the metal strips 360 so that no materials are ablated over the metal strips 360. The one ablative channel 390 extending down to the top of the active material 130 may be formed independently of the two ablative channels 380 extending down to the substrate 160, or alternatively may be formed after formation of the two ablative channels 380 extending down to the substrate 160 and after these channels have been filled with a conductive material (not shown), thereby allowing self-alignment of the one ablative channel 390 with respect to the two ablative channels 380. Conductive material (not shown) deposited in all the channels form source, and drain connections to the outer metal strips, thereby minimizing the length of the conductive material required.

FIG. 7c illustrates in cross-section an ablative film 125 and transistor fabrication process similar to that of the previous embodiment except that only a single ablative layer 170 is included. This process is appropriate in cases that the active layer 130 does not include an insulator on its bottom surface so that the source-drain contacts are made directly to the pre-patterned metal strips 360 upon deposition of the act layer 130. In this case, a gate dielectric is deposited over the active material before deposition of the fluid conductive material that forms the gate electrode. Advantageously, the channel ablated in ablative layer 170 can be self-aligned to the two metal strips which reflect laser radiation and reduce the temperature rise in the ablative material, that is, the laser radiation ablating channel 170 in FIG. 7c can extend over the metal strips.

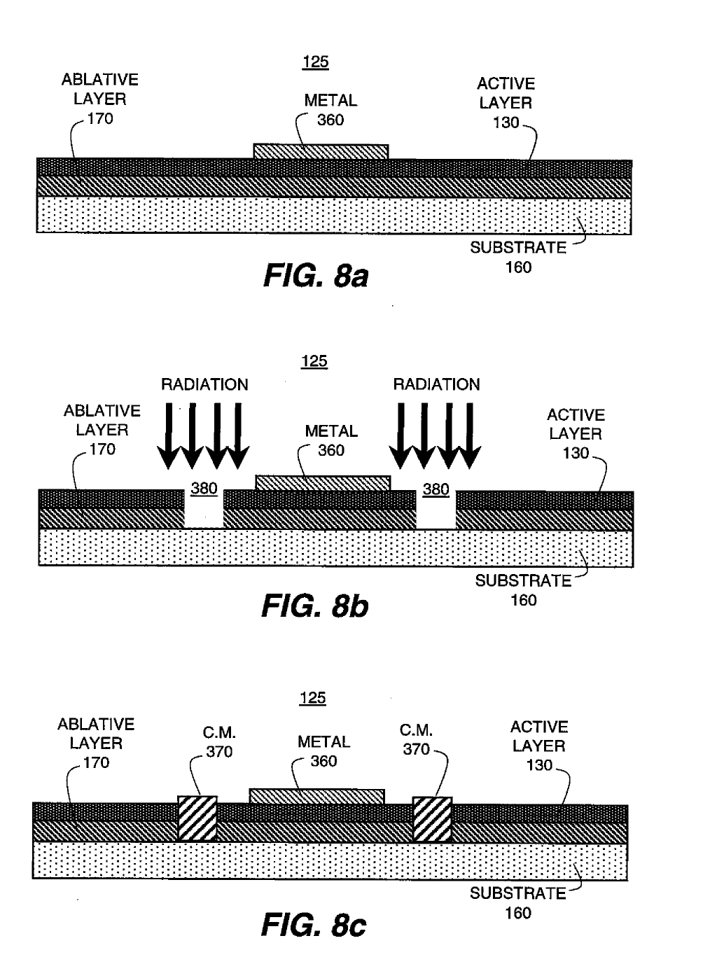

FIG. 8a illustrates in cross-section an embodiment of the ablative film 125 having a pre-deposited metal film 360 deposited as a single metal strip, in which the order of layers from bottom to top is substrate 160, ablative layer 170, active layer 130, and pre-deposited metal film 360. The pre-deposited metal film 360 is the gate electrode and lies over the active layer 130 and the ablative layer 170.

FIG. 8b illustrates in cross-section the ablative film 125 of FIG. 8a after formation, for example, by laser radiation from the topside, of two ablated channels 380 extending down to the substrate 160. The edge of each ablated channel 380 nearest the metal strip 360 is self-aligned to the adjacent edge of the metal strip 360 by virtue of the fact that the edge of the laser radiation defining the ablated channel 380 nearest the metal strip 360 (FIG. 8b) overlaps the metal strip 360, the metal strip 360 reflects the radiation substantially above the strip and thereby prevents ablation substantially above the strip. Advantageously, the active material 130 is not damaged, since it is preferably of the type which is typically processed at high temperatures. The edges of the active material 130 in the channels 380 have no dielectric insulator on their surfaces, since the active layer 130 has been fractured by the ablative process.

FIG. 8c illustrates in cross-section the ablative film 125 of FIG. 8b after the ablated channels 380 have been filled with a conductive material 370. The conductive materials 370 may be provided by deposition of a fluid conductive material, for example by inkjet printing. In FIG. 8c, the fluid conductive material is deposited, for example by inkjet printing or by dipping and wiping the sample, and then dried or annealed to form source and drain conductive material 370. The gate metal 360 lies over the active layer 130.

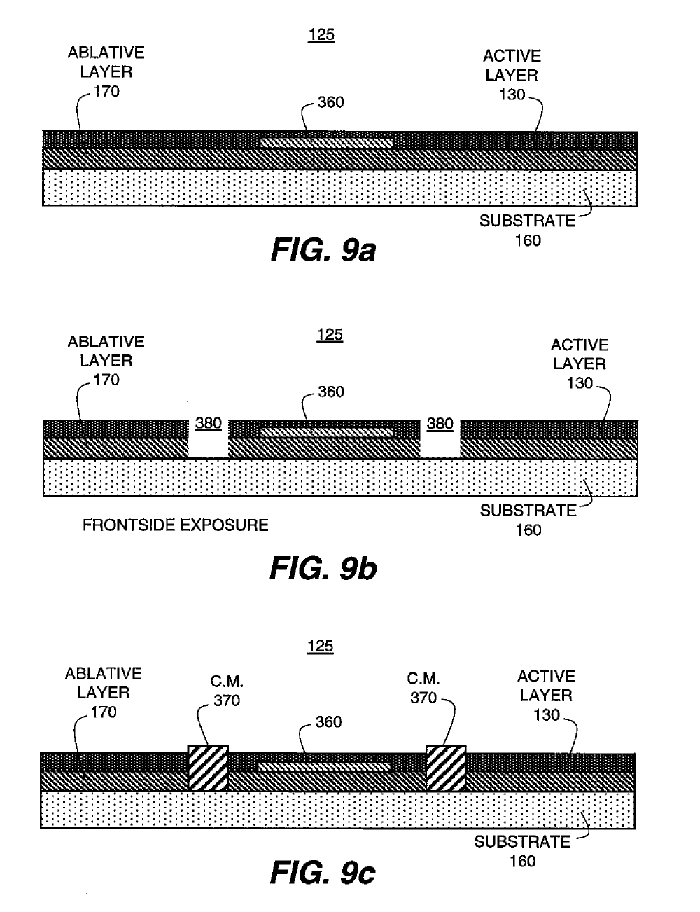

FIG. 9a illustrates an embodiment of the ablative film 125 having a pre-deposited metal film 360 deposited as a single metal strip, in which the order of layers from bottom to top is substrate 160, ablative layer 170, pre-deposited metal film 360, and active layer 130. The gate electrode lies between the ablative layer 170 and the active layer 130.

FIG. 9b illustrates in cross-section the ablative film 125 of FIG. 9a after formation, by laser radiation from the topside of the ablative film 125, of two ablated channels 380 extending down to the substrate 160. The edge of each ablated channel 380 nearest the metal strip 360 is self-aligned to the adjacent edge of the metal strip 360 by virtue of the fact that the edge of the laser radiation defining the ablated channel 380 nearest the metal strip 360 overlaps the metal strip 360, the metal strip 360 reflecting the radiation substantially above the strip 360 and reducing the temperature rise of the ablative layer in this region, thereby preventing ablation substantially above the strip 360 as shown in FIG. 8b.

FIG. 9c illustrates in cross-section the ablative film 125 of FIG. 9b after the ablated channels 380 have been filled with a conductive material 370. The conductive materials 370 may be provided by deposition of a fluid conductive material, for example by inkjet printing. In FIG. 9c, the fluid is deposited and dried or annealed to form source and drain conductive material.

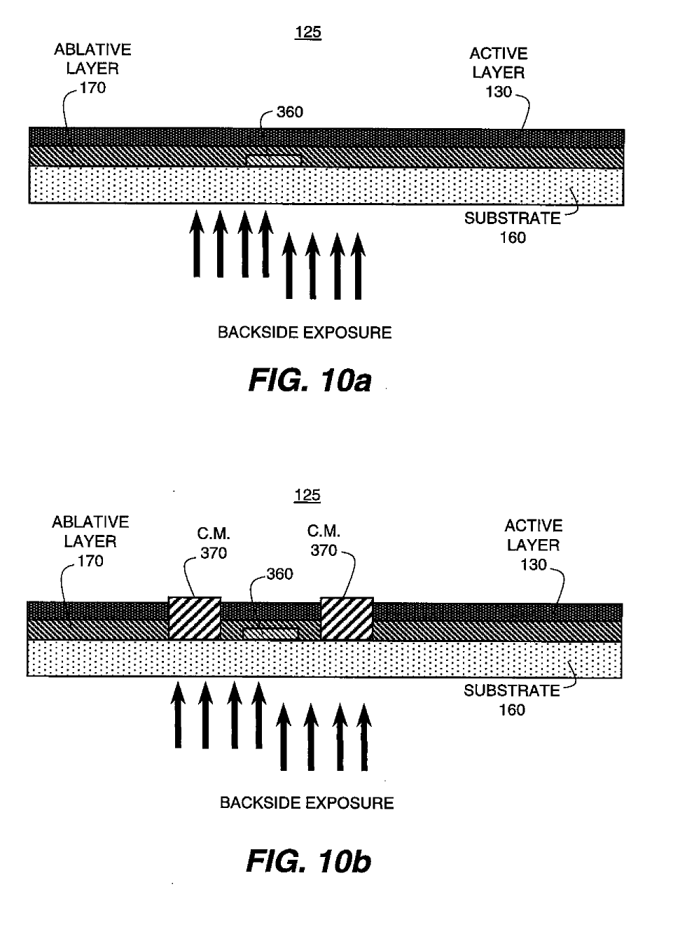

FIG. 10a illustrates an embodiment of the ablative film 125 having a metal film 360 deposited as a single metal strip, in which the order of layers from bottom to top is substrate 160, pre-deposited metal film 360, ablative layer 170, and active layer 130. The ablative layer 170 lies between the gate electrode 360 and the active layer 130 and is therefore part of the gate insulator of the transistor to be formed. In this regard the structure resembles that disclosed by Hoffman et al., U.S. Pat. No. 7,265,003, who describes a transistor structure in which the gate dielectric comprises a dual dielectric layer, however the processing sequence is very different from the currently contemplated invention.

FIG. 10b illustrates in cross-section the ablative film 125 of FIG. 10a after formation, by laser radiation from the bottom side of the ablative film 125, of two ablated channels extending to the substrate 160. The edge of each ablated channel nearest the metal strip 360 is self-aligned to the adjacent edge of the metal strip 360 by virtue of the fact that the edge of the laser radiation defining the ablated channel nearest the metal strip 360 overlaps the metal strip 360, the metal strip 360 reflecting the radiation substantially above the strip 360 and thereby preventing ablation substantially above the strip 360. The ablated channels have been filled with a conductive material 370 in FIG. 10b, similar to the previous embodiments. The substrate in FIGS. 10a and 10b is chosen to be transparent to the wavelength of the ablative radiation.

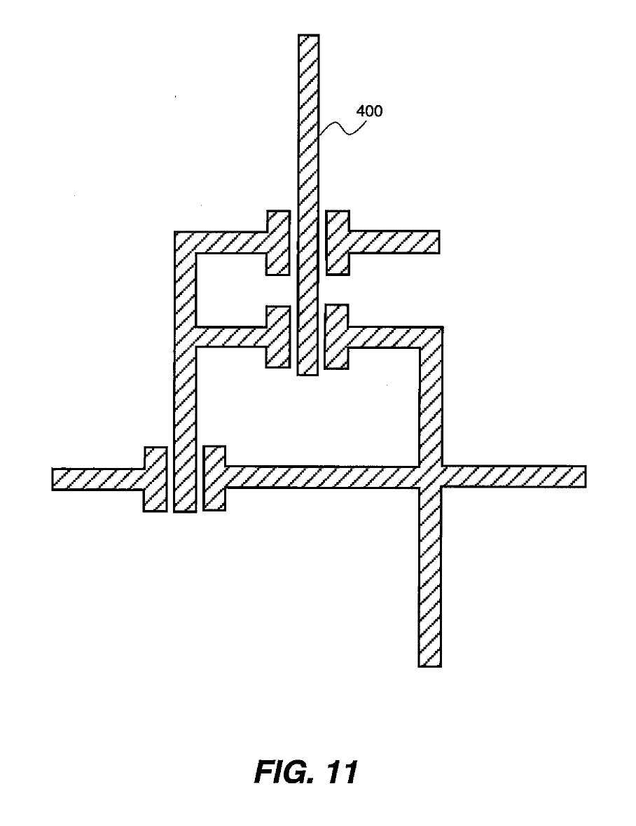

FIG. 11 shows a schematic top view of circuitry created by the embodiments described above, the dark lines representing electrical conductive interconnects 400, such as conductive materials deposited in ablated trenches or prepatterned metal films or both, illustrating the use of the present invention in building up systems comprising a plurality of the transistor structures described in detail. The present invention contemplates the use of large-area ablative films (multiple square meters) processed to contain thousands or millions of such transistor circuits.

The invention has been described with reference to a preferred embodiment. However, it will be appreciated that variations and modifications can be effected by a person of ordinary skill in the art without departing from the scope of the invention.

### PARTS LIST

5 ablative film
10 substrate
20 energy-absorbing layer
30 multiple layers
40 channel
50 altered absorbing layer
60 electrically conductive material
90 active element
100 surface
110 electrical connection
120 connecting material
125 ablative film
130 semiconductor active layer
160 substrate
170 ablative layer
175 second ablative layer
360 pre-deposited metal film (strip)
370 conductive material
380 two ablative channels
390 one ablative channel
400 interconnects

1. An ablative film comprising:
(a) a substrate;
(b) at least one ablative layer that is removable by exposure to radiation;
(c) one or more deposited conductors; and
(d) an active layer including a semiconductor material surrounded at least partially by a dielectric.

2. The ablative film as in claim 1, wherein the active layer is disposed between the metal and the ablative layer, and the deposited metal abuts the substrate.

3. The ablative film as in claim 2, wherein the deposited conductors are three spaced-apart deposited conductors and the active layer covers at least a portion of each deposited conductor.

4. The ablative film as in claim 2, wherein the deposited conductor is one conductor that forms a gate and the active layer entirely spans one dimension of the conductor, and two recess portions spans at least a portion of the conductor and respectively receive source and drain connections.

5. The ablative layer as in claim 2, wherein the deposited conductor is three-spaced apart deposited conductors; the active layer covers the centrally positioned deposited conductor in at least one dimension; and two recess portions each positioned between the centrally positioned deposited conductor and another of the deposited conductors.

6. The ablative film as in claim 1, wherein the active layer is disposed between the metal and the ablative layer, and further comprising a second ablative layer disposed between deposited conductor and the active layer and the second ablative layer abuts a substrate.

7. The ablative film as in claim 6, wherein the deposited conductor is three conductors and the active layer only covers the conductor in a center position, and two conductive materials that respectively form a source and drain are each disposed between two of the conductors and abuts the second ablative layer.

8. The ablative film as in claim 6, wherein the deposited conductor is two spaced-apart conductors and the active layer covers or substantially covers a dimension of each conductor; two recess portions are formed between the conductors that respectively receive source and drain connections and a gate is formed over the active layer.

9. The ablative film as in claim 2, wherein the deposited conductor is two spaced-apart conductors and the active layer is void of a dielectric at least on its bottom side and covers a dimension of each conductor so that a source and drain are formed, and a gate is formed over the active layer that is between the conductors.

10. The ablative film as in claim 1, wherein the active layer is disposed between the metal and the ablative layer, the ablative layer abuts the substrate and the deposited conductor is a single conductor.

11. The ablative layer as in claim 10 further comprising two conductive materials which respectively form a source and drain each disposed in the active layer and ablative layer laterally adjacent the deposited conductor.

12. The ablative layer as in claim 1, wherein the deposited conductor is disposed between the ablative layer and the active layer; the ablative layer abuts the substrate and the deposited conductor is a single conductor.

13. The ablative layer as in claim 12 further comprising two conductive materials disposed in the active later and ablative layer each laterally adjacent the conductor.

14. The ablative layer as in claim 1, wherein the ablative layer is disposed between the deposited conductor and the active layer; the deposited conductor abuts the substrate and the deposited conductor is a single conductor.

15. The ablative film as in claim 14 further comprising two conductive materials each disposed laterally adjacent the deposited conductor in the active layer and the ablative layer.

16. A method for creating transistor circuits, the method comprising the steps of:
(a) providing a substrate;
(b) providing at least one ablative layer that is removable by exposure to radiation;
(c) providing one or more deposited conductors;
(d) providing an active layer including a semiconductor material surrounded at least partially by a dielectric; and
(e) providing conductive materials, deposited in a plurality of ablated channels, electrically connecting a plurality of the transistor structures to form transistor circuits.
